(19) United States
(12) Patent Application Publication
(10) Pub. No.: US 2022/0131516 A1
(43) Pub. Date: Apr. 28, 2022

(54) DIPLEXER

(71) Applicant: Murata Manufacturing Co., Ltd., Nagaokakyo-shi (JP)

(72) Inventors: Yuutarou YAMAZAKI, Nagaokakyo-shi (JP); Hiroto MOTOYAMA, Nagaokakyo-shi (JP); Tetsuo TANIGUCHI, Nagaokakyo-shi (JP); Yuji KAMINISHI, Nagaokakyo-shi (JP)

(21) Appl. No.: 17/570,414

(22) Filed: Jan. 7, 2022

Related U.S. Application Data
(63) Continuation of application No. PCT/JP2020/025967, filed on Jul. 2, 2020.

(30) Foreign Application Priority Data
Aug. 10, 2019 (JP) 2019-148249

(51) Int. Cl. H03H 7/38; H03H 7/01

(52) U.S. Cl. CPC H03H 7/38; H03H 7/1766

(57) ABSTRACT

A diplexer includes a low-band band pass filter between a common input/output terminal and a low-band input/output terminal and a high-band band pass filter between the common input/output terminal and a high-band input/output terminal, wherein the low-band band pass filter includes LC resonators including a first-stage LC resonator to a final-stage LC resonator in order from the common input/output terminal toward the low-band input/output terminal, the high-band band pass filter includes LC resonators including a first-stage LC resonator to a final-stage LC resonator in order from the common input/output terminal toward the high-band input/output terminal, a matching capacitor is between the common input/output terminal and the low-band band pass filter, and the capacitance of a capacitor of the first-stage LC resonator of the low-band band pass filter is smaller than the capacitance of a capacitor of the final-stage LC resonator.

### CROSS REFERENCE TO RELATED APPLICATIONS

This application claims the benefit of priority to Japanese Patent Application No. 2019-148249 filed on Aug. 10, 2019 and is a Continuation Application of PCT Application No. PCT/JP2020/025967 filed on Jul. 2, 2020. The entire contents of each application are hereby incorporated herein by reference.

### BACKGROUND OF THE INVENTION

### 1. Field of the Invention

The present invention relates to diplexers and, more particularly, to a diplexer including a low-band band pass filter and a high-band band pass filter.

### 2. Description of the Related Art

Band pass filters are disclosed in WO 2007/119356A1 and WO 2018/100923A1. These band pass filters are each configured by capacitively coupling or magnetically coupling a plurality of LC resonators. Each LC resonator includes an inductor formed of a via conductor or a via conductor and a wiring conductor, and a capacitor formed of a ground electrode and an end-portion electrode provided on one end portion of the via conductor of this inductor.

A diplexer can be configured by combining a plurality of such band pass filters. For example, a diplexer can be configured by including a common input/output terminal, a low-band input/output terminal, and a high-band input/output terminal, providing a low-band band pass filter in between the common input/output terminal and the low-band input/output terminal, and providing a high-band band pass filter in between the common input/output terminal and the high-band input/output terminal.

In the case where such a diplexer is configured, usually, an impedance matching circuit is required. In the foregoing configuration, as the impedance matching circuit, for example, it is possible to provide an L-type LC low pass filter in between the common input/output terminal and the low-band band pass filter and an L-type LC high pass filter in between the common input/output terminal and the high-band band pass filter.

In the case where a LC low pass filter or a LC high pass filter is provided as the impedance matching circuit of a diplexer, insertion loss is increased.

Further, in the case where a diplexer is configured by providing capacitor electrodes or inductor electrodes in a multilayer board in which a plurality of base layers are stacked on top of each other, a great number of elements needs to be formed in the multilayer board when a LC low pass filter or a LC high pass filter is provided as the impedance matching circuit, and thus the size of the diplexer is increased.

### SUMMARY OF THE INVENTION

Preferred embodiments of the present invention provide diplexers each with a smaller insertion loss compared with when a LC low pass filter or a LC high pass filter is provided as an impedance matching circuit.

A diplexer according to a preferred embodiment of the present invention includes a common input/output terminal, a low-band input/output terminal, a high-band input/output terminal, a low-band band pass filter between the common input/output terminal and the low-band input/output terminal, a high-band band pass filter between the common input/output terminal and the high-band input/output terminal, wherein the low-band band pass filter includes a plurality of LC resonators, the plurality of LC resonators including a first-stage LC resonator to a final-stage LC resonator provided in order from the common input/output terminal toward the low-band input/output terminal, each of the plurality of LC resonators including an inductor and a capacitor, the high-band band pass filter includes a plurality of LC resonators including a first-stage LC resonator to a final-stage LC resonator provided in order from the common input/output terminal toward the high-band input/output terminal, each of the plurality of LC resonators including an inductor and a capacitor, a matching capacitor is provided between the common input/output terminal and the low-band band pass filter, and a capacitance of the capacitor of the first-stage LC resonator of the low-band band pass filter is smaller than a capacitance of the capacitor of the final-stage LC resonator of the low-band band pass filter.

A diplexer according to a preferred embodiment of the present invention includes a multilayer board including a plurality of base layers stacked on top of one another, wherein a plurality of via conductors, a plurality of capacitor electrodes, a first ground electrode, and a second ground electrode are in an inside of the multilayer board, a common input/output terminal, a low-band input/output terminal, a high-band input/output terminal, and a ground terminal are on a surface of the multilayer board, the ground terminal is connected to the first ground electrode and the second ground electrode, a plurality of sets of capacitors and inductors is provided between the common input/output terminal and the low-band input/output terminal, each of the plurality of sets of capacitors and inductors including a capacitor including the first ground electrode and the capacitor electrode that face one another and an inductor including a conductor including the via conductor connected between this capacitor electrode and the second ground electrode, the common input/output terminal is connected to a first set of the capacitor and the inductor via a matching capacitor, the matching capacitor including at least a pair of the capacitor electrodes that face one another, the low-band input/output terminal is connected to a second set of the capacitor and the inductor, and a capacitance of the capacitor of the first set of the capacitor and the inductor is smaller than a capacitance of the capacitor of the second set of the capacitor and the inductor.

Each of the diplexers according to preferred embodiments of the present invention has a smaller insertion loss compared with when a LC low pass filter or a LC high pass filter is provided as an impedance matching circuit.

Where diplexers according to preferred embodiments of the present invention each include a multilayer board including a plurality of base layers stacked on top of each other, an increase in size of the diplexer is reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an equivalent circuit diagram of a diplexer 100 according to a preferred embodiment of the present invention.

FIG. 2 is an exploded perspective view of the diplexer 100.

FIG. 3A is the Smith chart of S(1,1) of the diplexer 100, and FIG. 3B is the Smith chart of S(2,2) of the diplexer 100.

FIG. 4A is a frequency characteristic diagram of S(1,1) and S(1,3) of the diplexer 100, and FIG. 4B is a frequency characteristic diagram of S(2,2) and S(2,3) of the diplexer 100.

FIG. 5 is an equivalent circuit diagram of a diplexer 500 according to a comparative example.

FIG. 6A is a frequency characteristic diagram of S(1,1) and S(1,3) of the diplexer 500, and FIG. 6B is a frequency characteristic diagram of S(2,2) and S(2,3) of the diplexer 500.

### DETAILED DESCRIPTION OF THE PREFERRED EMBODIMENTS

Hereinafter, preferred embodiments of the present invention are described with reference to the drawings. Note that each preferred embodiment is provided for illustrative purposes only, and the present invention is not limited by the contents of the preferred embodiments. Further, contents described in different preferred embodiments may be combined and are also included in the present invention. Further, the drawings are provided to facilitate understanding of the specification, and they are in some cases drawn schematically. In some cases, ratios of dimensions of elements that are drawn or ratios of dimensions between the elements may not agree with those described in the specification. Further, in some cases, an element or elements described in the specification may be omitted from the drawings or may be drawn with abbreviation on the number of units thereof, or the like.

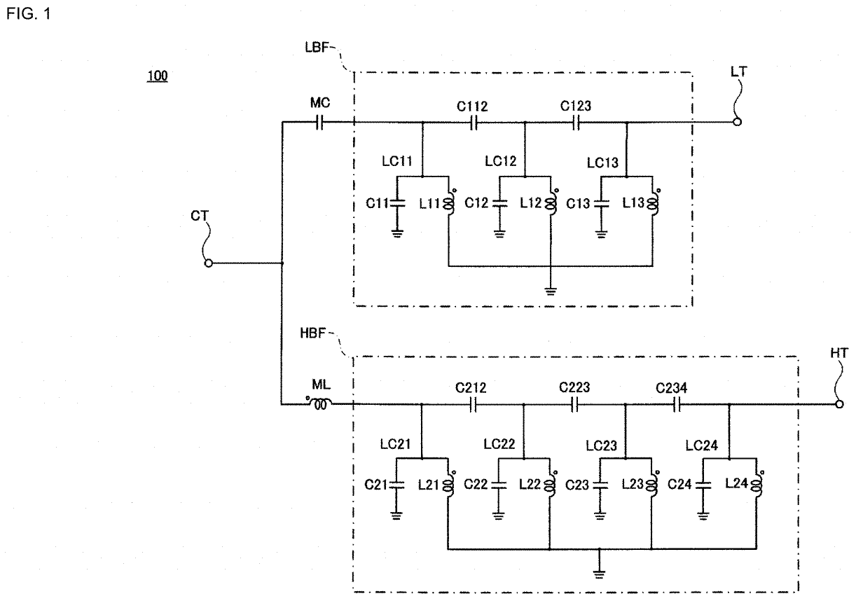

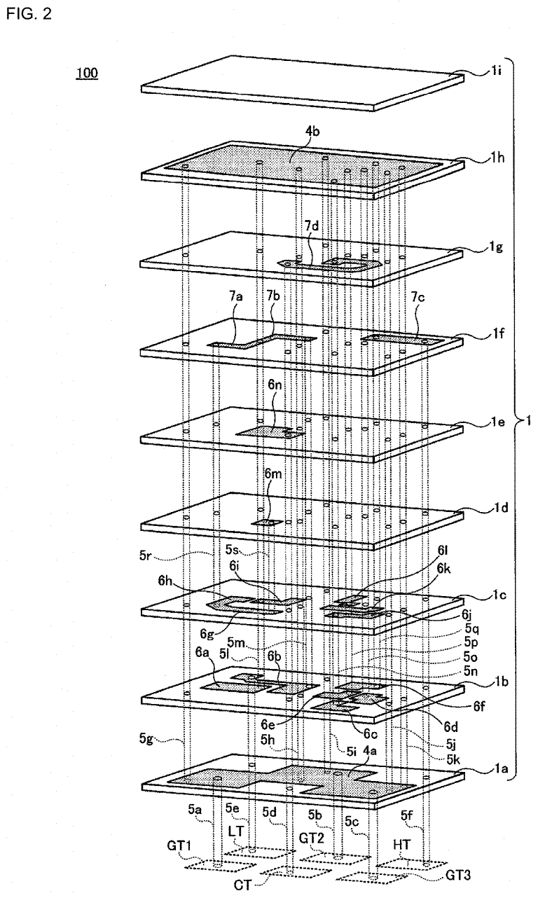

FIG. 1 and FIG. 2 illustrate a diplexer 100 according to a preferred embodiment of the present invention. FIG. 1 is an equivalent circuit diagram of the diplexer 100, and FIG. 2 is an exploded perspective view of the diplexer 100.

First, referring to FIG. 1, an equivalent circuit of the diplexer 100 is described.

The diplexer 100 includes a common input/output terminal CT, a low-band input/output terminal LT, and a high-band input/output terminal HT.

A low-band band pass filter LBF is provided between the common input/output terminal CT and the low-band input/output terminal LT. A high-band band pass filter HBF is provided between the common input/output terminal CT and the high-band input/output terminal HT. The center frequency of pass band of the low-band band pass filter LBF is lower than the center frequency of pass band of the high-band band pass filter HBF.

An impedance matching capacitor MC is provided between the common input/output terminal CT and the low-band band pass filter LBF. Further, an impedance matching inductor ML is provided between the common input/output terminal CT and the high-band band pass filter HBF.

The low-band band pass filter LBF includes a first-stage LC resonator LC11, a second-stage LC resonator LC12, and a third-stage LC resonator LC13 in this order from the common input/output terminal CT toward the low-band input/output terminal LT. A three-stage band pass filter is provided by magnetically coupling or capacitively coupling these three LC resonators.

The first-stage LC resonator LC11 is a LC parallel resonator in which a capacitor C11 and an inductor L11 are connected in parallel. The second-stage LC resonator LC12 is a LC parallel resonator in which a capacitor C12 and an inductor L12 are connected in parallel. The third-stage LC resonator LC13 is a LC parallel resonator in which a capacitor C13 and an inductor L13 are connected in parallel.

The first-stage LC resonator LC11 and the second-stage LC resonator LC12 are primarily capacitively coupled by a coupling capacitor C112. The second-stage LC resonator LC12 and the third-stage LC resonator LC13 are primarily capacitively coupled by a coupling capacitor C123.

Between the common input/output terminal CT and the low-band input/output terminal LT, the matching capacitor MC, the coupling capacitor C112, and the coupling capacitor C123 are provided in series in this order. The first-stage LC resonator LC11 is provided between ground and a connecting point of the matching capacitor MC and the coupling capacitor C112. The second-stage LC resonator LC12 is provided between the ground and a connecting point of the coupling capacitor C112 and the coupling capacitor C123. The third-stage LC resonator LC13 is provided between the ground and a connecting point of the coupling capacitor C123 and the low-band input/output terminal LT.

The high-band band pass filter HBF includes a first-stage LC resonator LC21, a second-stage LC resonator LC22, a third-stage LC resonator LC23, and a fourth-stage LC resonator LC24 in this order from the common input/output terminal CT toward the high-band input/output terminal HT. A four-stage band pass filter is provided by magnetically coupling or capacitively coupling these four LC resonators.

The first-stage LC resonator LC21 is a LC parallel resonator in which a capacitor C21 and an inductor L21 are connected in parallel. The second-stage LC resonator LC22 is a LC parallel resonator in which a capacitor C22 and an inductor L22 are connected in parallel. The third-stage LC resonator LC23 is a LC parallel resonator in which a capacitor C23 and an inductor L23 are connected in parallel. The fourth-stage LC resonator LC24 is a LC parallel resonator in which a capacitor C24 and an inductor L24 are connected in parallel.

The first-stage LC resonator LC21 and the second-stage LC resonator LC22 are primarily capacitively coupled by a coupling capacitor C212. The second-stage LC resonator LC22 and the third-stage LC resonator LC23 are primarily capacitively coupled by a coupling capacitor C223. The third-stage LC resonator LC23 and the fourth-stage LC resonator LC24 are primarily capacitively coupled by a coupling capacitor C234.

Between the common input/output terminal CT and the high-band input/output terminal HT, the matching inductor ML, the coupling capacitor C212, the coupling capacitor C223, and the coupling capacitor C234 are provided in series in this order. The first-stage LC resonator LC21 is provided between the ground and a connecting point of the matching inductor ML and the coupling capacitor C212. The second-stage LC resonator LC22 is provided between the ground and a connecting point of the coupling capacitor C212 and the coupling capacitor C223. The third-stage LC resonator LC23 is provided between the ground and a connecting point of the coupling capacitor C223 and the coupling capacitor C234. The fourth-stage LC resonator LC24 is provided between the ground and a connecting point of the coupling capacitor C224 and the high-band input/output terminal HT.

Next, referring to FIG. 2, the diplexer 100 including a multilayer board 1 including a plurality of base layers 1a to 1i stacked on top of each other is described.

As described above, the diplexer 100 includes the multilayer board 1 in which the plurality of base layers 1a to 1i are stacked on top of each other. The multilayer board 1 (base layers 1a to 1i) can be made of, for example, a low temperature co-fired ceramic. However, the material of the multilayer board 1 is not limited to the low temperature co-fired ceramic and may alternatively be another kind of ceramic, a resin, or the like.

Configurations of the respective base layers 1a to 1i are described below.

The common input/output terminal CT, the low-band input/output terminal LT, the high-band input/output terminal HT, and three ground terminals GT1, GT2, and GT3 are provided on a lower side principal surface of the base layer 1a in FIG. 2. In FIG. 2, for the convenience of illustration, the common input/output terminal CT, the low-band input/output terminal LT, the high-band input/output terminal HT, and the ground terminals GT1, GT2, and GT3 are illustrated by dashed line and separated from the base layer 1a.

A ground electrode 4a is provided on an upper side principal surface of the base layer 1a. In some cases, the ground electrode 4a is referred to as a first ground electrode.

Via conductors 5a, 5b, 5c, 5d, 5e, and 5f penetrate through both principal surfaces of the base layer 1a.

Capacitor electrodes 6a, 6b, 6c, 6d, 6e, and 6f are provided on an upper side principal surface of the base layer 1b.

The via conductors 5d, 5e, and 5f and new via conductors 5g, 5h, 5i, 5j, and 5k penetrate through both principal surfaces of the base layer 1b.

Capacitor electrodes 6g, 6h, 6i, 6j, 6k, and 6l are provided on an upper side principal surface of the base layer 1c. The capacitor electrode 6g and the capacitor electrode 6h are provided as a single unit. That is to say, the capacitor electrode 6g is extended in the planar direction to define the capacitor electrode (extension electrode) 6h.

The via conductors 5d, 5f, 5g, 5h, 5i, 5j, and 5k and new via conductors 5l, 5m, 5n, 5o, 5p, and 5q penetrate through both principal surfaces of the base layer 1c.

A capacitor electrode 6m is provided on an upper side principal surface of the base layer 1d.

The via conductors 5d, 5f, 5g, 5h, 5i, 5j, 5k, 5l, 5m, 5n, 5o, 5p, and 5q and new via conductors 5r and 5s penetrate through both principal surfaces of the base layer 1d.

A capacitor electrode 6n is provided on an upper side principal surface of the base layer 1e.

The via conductors 5d, 5f, 5g, 5h, 5i, 5j, 5k, 5l, 5m, 5n, 5o, 5p, 5q, and 5r penetrate through both principal surfaces of the base layer 1e.

Planar line electrodes 7a, 7b, and 7c are provided on an upper side principal surface of the base layer 1f. The planar line electrode 7a is connected to the planar line electrode 7b.

The via conductors 5d, 5f, 5g, 5h, 5i, 5j, 5k, 5l, 5m, 5n, 5o, 5p, 5q, and 5r penetrate through both principal surfaces of the base layer 1f.

A planar line electrode 7d is provided on an upper side principal surface of the base layer 1g.

The via conductors 5d, 5g, 5h, 5i, 5j, 5k, 5l, 5n, 5o, 5p, and 5q penetrate through both principal surfaces of the base layer 1g.

A ground electrode 4b is provided on an upper side principal surface of the base layer 1h. In some cases, the ground electrode 4a is referred to as a second ground electrode.

The via conductors 5g, 5h, 5i, 5j, 5k, 5l, 5n, 5o, 5p, and 5q penetrate through both principal surfaces of the base layer 1h.

The base layer 1i is a protection layer, and no electrode is provided therein.

Materials of the common input/output terminal CT, the low-band input/output terminal LT, the high-band input/output terminal HT, the ground terminals GT1, GT2, and GT3, the ground electrodes 4a and 4b, the via conductors 5a to 5s, the capacitor electrodes 6a to 6n, the planar line electrodes 7a to 7d may be determined arbitrary. However, for example, copper, silver, aluminum, or the like, or an alloy thereof may be used as a main component of the material. Note that plating layers may be further provided on surfaces of the common input/output terminal CT, the low-band input/output terminal LT, the high-band input/output terminal HT, and the ground terminals GT1, GT2, and GT3.

Next, relationships of connections among the common input/output terminal CT, the low-band input/output terminal LT, the high-band input/output terminal HT, the ground terminals GT1, GT2, and GT3, the ground electrodes 4a and 4b, the via conductors 5a to 5s, the capacitor electrodes 6a to 6n, and the planar line electrodes 7a to 7d in the diplexer 100 are described.

The ground terminal GT1 is connected to the ground electrode 4a by the via conductor 5a. The ground terminal GT2 is connected to the ground electrode 4a by the via conductor 5b. The ground terminal GT3 is connected to the ground electrode 4a by the via conductor 5c.

The ground electrode 4a is connected to the ground electrode 4b by the via conductors 5g, 5h, 5i, 5j, and 5k.

The common input/output terminal CT is connected to the capacitor electrode 6n by the via conductor 5d.

The capacitor electrode 6m is connected to the capacitor electrode 6g by the via conductor 5s. As described above, the capacitor electrode 6g and the capacitor electrode 6h are provided as a single unit.

The capacitor electrode 6a is connected to the capacitor electrode 6i by the via conductor 5l.

The capacitor electrode 6b is connected to the low-band input/output terminal LT by the via conductor 5e.

The capacitor electrode 6g is connected to one end portion of the planar line electrode 7a by the via conductor 5r.

The capacitor electrode 6a is connected to a connecting point of the planar line electrode 7a and the planar line electrode 7b by the via conductor 5l.

The capacitor electrode 6b is connected to one end portion of the planar line electrode 7b by the via conductor 5m.

The connecting point of the planar line electrode 7a and the planar line electrode 7b is connected to the ground electrode 4b by the via conductor 5l.

Meanwhile, the via conductor 5d connected to the common input/output terminal CT is connected to one end portion of the planar line electrode 7d.

The other end portion of the planar line electrode 7d is connected to the capacitor electrode 6j by the via conductor 5n.

The capacitor electrode 6e is connected to the capacitor electrode 6l by the via conductor 5p.

The capacitor electrode 6f is connected to one end portion of the planar line electrode 7c by the via conductor 5q.

The other end portion of the planar line electrode 7c is connected to the high-band input/output terminal HT by the via conductor 5f.

The capacitor electrode 6c is connected to the ground electrode 4b by the via conductor 5n.

The capacitor electrode 6d is connected to the ground electrode 4b by the via conductor 5o.

The capacitor electrode 6e is connected to the ground electrode 4b by the via conductor 5p.

The capacitor electrode 6f is connected to the ground electrode 4b by the via conductor 5q.

Next, a relationship between the equivalent circuit of the diplexer 100 illustrated in FIG. 1 and the common input/output terminal CT, the low-band input/output terminal LT, the high-band input/output terminal HT, the ground terminals GT1, GT2, and GT3, the ground electrodes 4a and 4b, the via conductors 5a to 5s, the capacitor electrodes 6a to 6n, and the planar line electrodes 7a to 7d illustrated in FIG. 2 is described.

The matching capacitor MC is defined by a capacitance between the capacitor electrode 6n and the capacitor electrode 6m.

Each LC resonator of the low-band band pass filter LBF includes an inductor including a via conductor and a capacitor including a ground electrode and an end-portion electrode provided at one end portion of this via conductor.

The inductor L11 of the first-stage LC resonator LC11 is defined by inductance components of the via conductor 5r, the planar line electrode 7a, and a first portion of the via conductor 5l. The via conductor 5r is the via conductor that connects the capacitor electrode 6g and the planar line electrode 7a. The first portion of the via conductor 5l is the portion of the via conductor 5l that connects the ground electrode 4b and the connecting point of the planar line electrode 7a and the planar line electrode 7b. Instead of connecting the via conductor 5r to the planar line electrode 7a, the via conductor 5r may be directly connected to the ground electrode 4b, and the planar line electrode 7a may be omitted. The capacitor C11 of the first-stage LC resonator LC11 is defined by a capacitance between the capacitor electrode (end-portion electrode) 6g, which is provided at one end portion of the via conductor 5r, and the ground electrode 4a.

The inductor L12 of the second-stage LC resonator LC12 is defined by an inductance component of the via conductor 5l. The via conductor 5l is the via conductor that connects the capacitor electrode 6a and the ground electrode 4b. The capacitor C12 of the second-stage LC resonator LC12 is defined by a capacitance between the capacitor electrode (end-portion electrode) 6a, which is provided at one end portion of the via conductor 5l, and the ground electrode 4a.

The inductor L13 of the third-stage LC resonator LC13 is defined by inductance components of the via conductor 5m, the planar line electrode 7b, and the first portion of the via conductor 5l. The via conductor 5m is the via conductor that connects the capacitor electrode 6b and the planar line electrode 7b. The first portion of the via conductor 5l is the portion of the via conductor 5l that connects the ground electrode 4b and the connecting point of the planar line electrode 7a and the planar line electrode 7b. Instead of connecting the via conductor 5m to the planar line electrode 7b, the via conductor 5m may be directly connected to the ground electrode 4b, and the planar line electrode 7b may be omitted. The capacitor C13 of the third-stage LC resonator LC13 is defined by a capacitance between the capacitor electrode (end-portion electrode) 6b, which is provided at one end portion of the via conductor 5m, and the ground electrode 4a.

In the present preferred embodiment, portions of the via conductors of the first-stage LC resonator LC11 and the third-stage LC resonator LC13 share the first portion of the via conductor 5l and are connected to the ground electrode. However, the configuration is not limited thereto. It is possible to separate the planar line electrode 7a and the planar line electrode 7b and separately provide a via conductor connecting a separated end portion of the planar line electrode 7a and the ground electrode 4b and a via conductor connecting a separated end portion of the planar line electrode 7b and the ground electrode 4b.

In the low-band band pass filter LBF, the coupling capacitor C112 is defined by a capacitance between the capacitor electrode 6h and the capacitor electrode 6a. The coupling capacitor C123 is defined by a capacitance between the capacitor electrode 6i and the capacitor electrode 6b.

Further, the matching inductor ML is defined by inductance components of a first portion of the via conductor 5d and planar line electrode 7d. The first portion of the via conductor 5d is the portion of the via conductor 5d that connects the capacitor electrode 6n and the planar line electrode 7d.

Each LC resonator of the high-band band pass filter HBF includes an inductor defined by a via conductor and a capacitor defined by a ground electrode and an end-portion electrode provided at one end portion of this via conductor.

The inductor L21 of the first-stage LC resonator LC21 is defined by an inductance component of the via conductor 5n that connects the capacitor electrode 6c and the ground electrode 4b. The capacitor C21 of the first-stage LC resonator LC21 is defined by a capacitance between the capacitor electrode (end-portion electrode) 6c, which is provided at one end portion of the via conductor 5n, and the ground electrode 4a.

The inductor L22 of the second-stage LC resonator LC22 is defined by an inductance component of the via conductor 5o that connects the capacitor electrode 6d and the ground electrode 4b. The capacitor C22 of the second-stage LC resonator LC22 is defined by a capacitance between the capacitor electrode (end-portion electrode) 6d, which is provided at one end portion of the via conductor 5o, and the ground electrode 4a.

The inductor L23 of the third-stage LC resonator LC23 is defined by an inductance component of the via conductor 5p that connects the capacitor electrode 6e and the ground electrode 4b. The capacitor C23 of the third-stage LC resonator LC23 is defined by a capacitance between the capacitor electrode (end-portion electrode) 6e, which is provided at one end portion of the via conductor 5p, and the ground electrode 4a.

The inductor L24 of the fourth-stage LC resonator LC24 is defined by an inductance component of the via conductor 5q that connects the capacitor electrode 6f and the ground electrode 4b. The capacitor C24 of the fourth-stage LC resonator LC24 is defined by a capacitance between the capacitor electrode (end-portion electrode) 6f, which is provided at one end portion of the via conductor 5q, and the ground electrode 4a.

In the high-band band pass filter HBF, the coupling capacitor C212 is defined by a capacitance between the capacitor electrode 6j and the capacitor electrode 6d. The coupling capacitor C223 is defined by a capacitance between the capacitor electrode 6d and the capacitor electrode 6k and a capacitance between the capacitor electrode 6k and the capacitor electrode 6e, in which the capacitances are connected in series. The coupling capacitor C234 is defined by a capacitance between the capacitor electrode 6l and the capacitor electrode 6f.

The diplexer 100 may be fabricated by a known fabrication method that has been used for fabricating diplexers.

In the diplexer 100 including the equivalent circuit and the structure described above, the matching capacitor MC is provided between the common input/output terminal CT and the low-band band pass filter LBF to make the capacitance of the capacitor C11 of the first-stage LC resonator LC11 smaller than the capacitance of the capacitor C13 of the third-stage (final-stage) LC resonator LC13 in the low-band band pass filter LBF, and the matching inductor ML is provided between the common input/output terminal CT and the high-band band pass filter HBF to make the capacitance of the capacitor C21 of the first-stage LC resonator LC21 larger than the capacitance of the capacitor C24 of the fourth-stage (final-stage) LC resonator LC24 in the high-band band pass filter HBF. Therefore, impedance matching between the low-band band pass filter LBF and the high-band band pass filter HBF is achieved.

The capacitance of each capacitor is obtained from the distance between opposite electrodes of a capacitor in the stacking direction and the overlapping area of the opposite electrodes when looking from the stacking direction.

Because the diplexer 100 uses such a matching method, the insertion loss is smaller compared with cases where a LC low pass filter or a LC high pass filter is used as a matching circuit.

Further, because the diplexer 100 uses such matching method, in the case where the diplexer 100 is provided in the multilayer board 1, a smaller number of electronic component elements is required for matching, and an increase in size is reduced or prevented.

The diplexer 100 is configured such that in the low-band band pass filter LBF, in order to make the capacitance of the capacitor C11 of the first-stage LC resonator LC11 smaller than the capacitance of the capacitor C13 of the third-stage LC resonator LC13, the distance between the ground electrode 4a and the capacitor electrode 6g that are included in the capacitor C11 is greater than the distance between the ground electrode 4a and the capacitor electrode 6a that are included in the capacitor C13. Further, when looking from the stacking direction of the multilayer board 1, the area of the capacitor electrode 6g of the capacitor C11, which faces the ground electrode 4a, is smaller than the area of the capacitor electrode 6a of the capacitor C13, which faces the ground electrode 4a.

Further, the diplexer 100 is configured such that in the high-band band pass filter HBF, in order to make the capacitance of the capacitor C21 of the first-stage LC resonator LC21 smaller than the capacitance of the capacitor C24 of the fourth-stage (final-stage) LC resonator LC24, the area of the capacitor electrode 6c of the capacitor C21, which faces the ground electrode 4a, is larger than the area of the capacitor electrode 6f of the capacitor C24, which faces the ground electrode 4a, when looking from the stacking direction of the multilayer board 1.

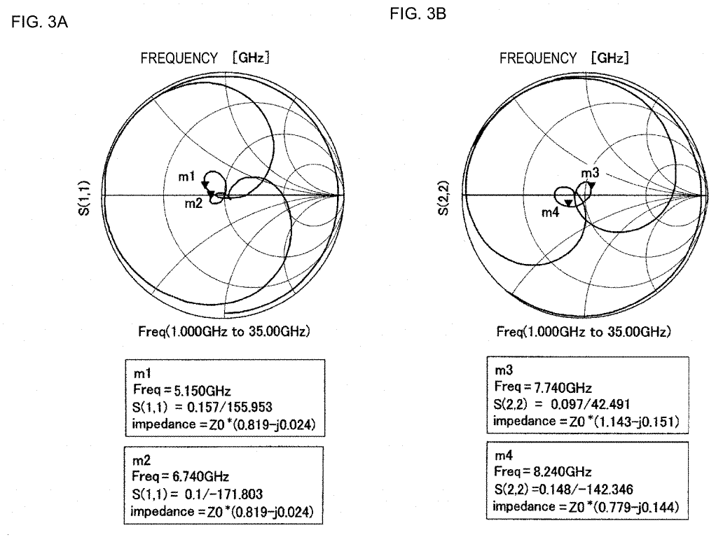

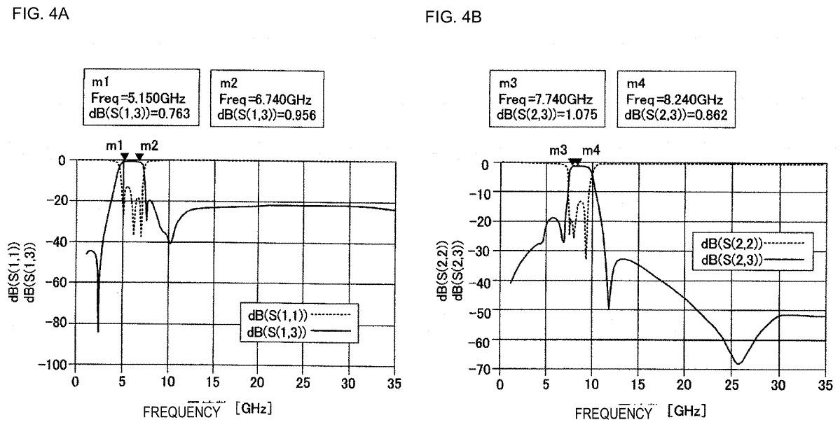

Characteristics of the diplexer 100 are illustrated in FIGS. 3A and 3B and FIGS. 4A and 4B. Note that FIG. 3A is the Smith chart of S(1,1), and FIG. 3B is the Smith chart of S(2,2). Further, FIG. 4A is a frequency characteristic diagram of S(1,1) and S(1,3), and FIG. B is a frequency characteristic diagram of S(2,2) and S(2,3). The low-band input/output terminal LT is the first terminal, the high-band input/output terminal HT is the second terminal, and the common input/output terminal CT is the third terminal.

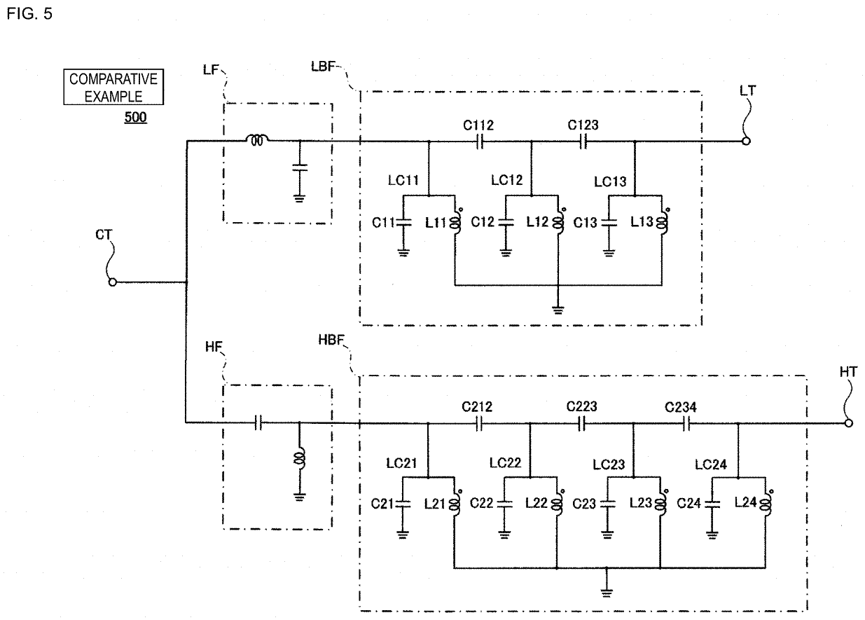

For the purpose of comparison, a diplexer 500 according to a comparative example illustrated in FIG. 5 is described. The diplexer 500 is provided by changing a portion of the configuration of the diplexer 100. Specifically, in the diplexer 500, instead of the matching capacitor MC, a L-type LC low pass filter LF is provided between the common input/output terminal CT and the low-band band pass filter LBF, and instead of the matching inductor ML, a L-type LC high pass filter HF is provided between the common input/output terminal CT and the high-band band pass filter HBF. Further, in the low-band band pass filter LBF, the capacitance of the capacitor C11 of the first-stage LC resonator LC11 is equal to the capacitance of the capacitor C13 of the third-stage (final-stage) LC resonator LC13, and in the high-band band pass filter HBF, the capacitance of the capacitor C21 of the first-stage LC resonator LC21 is equal to the capacitance of the capacitor C24 of the fourth-stage (final-stage) LC resonator LC24.

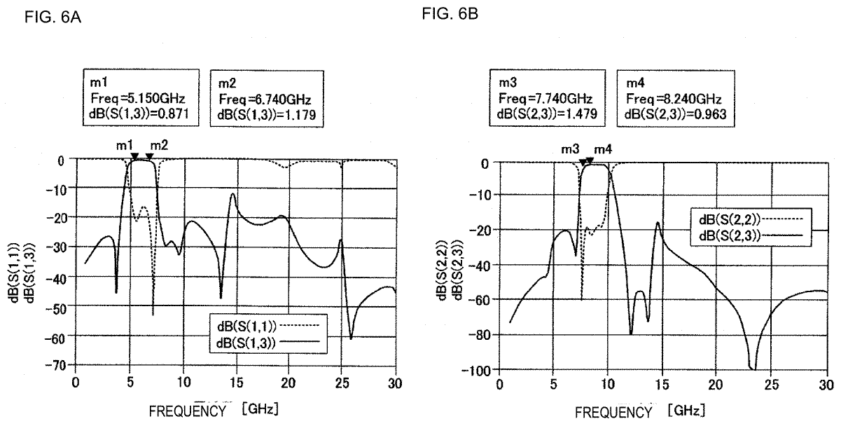

Characteristics of the diplexer 500 are illustrated in FIGS. 6A and 6B. Note that FIG. 6A is a frequency characteristic diagram of S(1,1) and S(1,3), and FIG. 6B is a frequency characteristic diagram of S(2,2) and S(2,3). Here, the low-band input/output terminal LT is the first terminal, the high-band input/output terminal HT is the second terminal, and the common input/output terminal CT is the third terminal.

As can be seen from FIGS. 3A and 3B, in the diplexer 100, impedance matching is effectively achieved.

Further, as can be seen from comparison between FIGS. 4A and 4B and FIGS. 6A and 6B, the diplexer 100 according to the present preferred embodiment has a smaller insertion loss compared with the diplexer 500 according to the comparative example.

In the diplexer 100, by changing the width of the capacitor electrode 6g and changing the area where the capacitor electrode 6g and the ground electrode 4a face each other, the capacitance of the capacitor C11 of the first-stage LC resonator LC11 of the low-band band pass filter LBF can be adjusted, and thus the impedance can be adjusted.

The diplexer 100 according to the present preferred embodiment has been described. However, it is to be understood that the diplexer of the present invention is not limited to the foregoing preferred embodiments, and that various modifications may be made within the scope of the present invention.

For example, in the diplexer 100, the low-band band pass filter LBF includes three stages, and the high-band band pass filter HBF includes four stages. However, the number of stages in each filter is arbitrary and may be changed separately.

Further, in the diplexer 100, in the low-band band pass filter LBF and the high-band band pass filter HBF, adjacent LC resonators are capacitively coupled to each other. However, the capacitive coupling may be changed to magnetic coupling.

In a diplexer according to a preferred embodiment of the present invention, it is also preferable to further include a multilayer board including a plurality of base layers stacked on top of each other, wherein the inductor of the LC resonator of the low-band band pass filter includes a via conductor in the multilayer board, and the capacitor is defined by a capacitance between an end-portion electrode provided at one end portion of the via conductor and a ground electrode, which are provided between different layers of the multilayer board.

Further, it is also preferable that a distance between the end-portion electrode of the first-stage LC resonator of the low-band band pass filter and the ground electrode is greater than a distance between the end-portion electrode of the final-stage LC resonator of the low-band band pass filter and the ground electrode. In this case, it becomes possible to easily make the capacitance of the capacitor of the first-stage LC resonator of the low-band band pass filter smaller than the capacitance of the capacitor of the final-stage LC resonator of the low-band band pass filter.

Further, it is also preferable that when viewed in a stacking direction of the multilayer board, an overlapping area of the end-portion electrode of the first-stage LC resonator of the low-band band pass filter and the ground electrode is smaller than an overlapping area of the end-portion electrode of the final-stage LC resonator of the low-band band pass filter and the ground electrode. In this case, it also becomes possible to easily make the capacitance of the capacitor of the first-stage LC resonator of the low-band band pass filter smaller than the capacitance of the capacitor of the final-stage LC resonator of the low-band band pass filter.

Further, it is also preferable that the capacitor of the first-stage LC resonator of the low-band band pass filter is defined by a capacitance between the end-portion electrode and the ground electrode, the capacitor of the second-stage LC resonator of the low-band band pass filter is defined by a capacitance between the end-portion electrode and the ground electrode, the ground electrode included in the capacitor of the first-stage LC resonator is same as the ground electrode included in the capacitor of the second-stage LC resonator, this ground electrode, the end-portion electrode of the second-stage LC resonator, and the end-portion electrode of the first-stage LC resonator are provided on different layers of the multilayer board, and the end-portion electrode of the second-stage LC resonator and an extension electrode include overlapping portions when viewed from a stacking direction of the multilayer board, the extension electrode being provided by extending the end-portion electrode of the first-stage LC resonator in a planar direction along a same layer as this end-portion electrode. In this case, it becomes possible to capacitively couple the first-stage LC resonator and the second-stage LC resonator.

Further, it is also preferable that a matching inductor is provided between the common input/output terminal and the high-band band pass filter, and a capacitance of the capacitor of the first-stage LC resonator of the high-band band pass filter is larger than a capacitance of the capacitor of the final-stage LC resonator of the high-band band pass filter. In this case, impedance matching is effectively achieved.

In this case, it is also preferable to further include a multilayer board including a plurality of base layers stacked on top of each other, wherein the inductor of the LC resonator of the high-band band pass filter includes a via conductor provided in the multilayer board, and the capacitor is defined by a capacitance between an end-portion electrode and a ground electrode, which are provided between different layers of the multilayer board, and when viewed in the stacking direction of the multilayer board, an overlapping area of the end-portion electrode of the first-stage LC resonator of the high-band band pass filter and the ground electrode is larger than an overlapping area of the end-portion electrode of the final-stage LC resonator of the high-band band pass filter and the ground electrode. In this case, it becomes possible to easily make the capacitance of the capacitor of the first-stage LC resonator of the high-band band pass filter larger than the capacitance of the capacitor of the final-stage LC resonator of the high-band band pass filter.

In a diplexer according to a preferred embodiment of the present invention, it is also preferable that a planar line electrode is further provided in an inside of the multilayer board, and the inductor includes a conductor including the via conductor and the planar line electrode. In this case, it becomes possible to easily adjust the inductance value of the inductor.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A diplexer comprising:
a common input/output terminal;
a low-band input/output terminal;
a high-band input/output terminal;
a low-band band pass filter between the common input/output terminal and the low-band input/output terminal; and
a high-band band pass filter between the common input/output terminal and the high-band input/output terminal; wherein
the low-band band pass filter includes a plurality of LC resonators including a first-stage LC resonator to a final-stage LC resonator in order from the common input/output terminal toward the low-band input/output terminal, each of the plurality of LC resonators including an inductor and a capacitor;
the high-band band pass filter includes a plurality of LC resonators including a first-stage LC resonator to a final-stage LC resonator in order from the common input/output terminal toward the high-band input/output terminal, each of the plurality of LC resonators of the high-band pass filter including an inductor and a capacitor;
a matching capacitor is between the common input/output terminal and the low-band band pass filter; and
a capacitance of the capacitor of the first-stage LC resonator of the low-band band pass filter is smaller than a capacitance of the capacitor of the final-stage LC resonator of the low-band band pass filter.

2. The diplexer according to claim 1 further comprising:
a multilayer board including a plurality of base layers stacked on top of one another; wherein
the inductor of the LC resonator of the low-band band pass filter includes a via conductor in the multilayer board, and the capacitor is defined by a capacitance between an end-portion electrode at one end portion of the via conductor and a ground electrode, which are between different layers of the multilayer board.

3. The diplexer according to claim 2, wherein a distance between the end-portion electrode of the first-stage LC resonator of the low-band band pass filter and the ground electrode is greater than a distance between the end-portion electrode of the final-stage LC resonator of the low-band band pass filter and the ground electrode.

4. The diplexer according to claim 2, wherein, when viewed in a stacking direction of the multilayer board, an overlapping area of the end-portion electrode of the first-stage LC resonator of the low-band band pass filter and the ground electrode is smaller than an overlapping area of the end-portion electrode of the final-stage LC resonator of the low-band band pass filter and the ground electrode.

5. The diplexer according to claim 2, wherein
the capacitor of the first-stage LC resonator of the low-band band pass filter is defined by a capacitance between the end-portion electrode and the ground electrode;
the capacitor of the second-stage LC resonator of the low-band band pass filter is defined by a capacitance between the end-portion electrode and the ground electrode;
the ground electrode included in the capacitor of the first-stage LC resonator and the ground electrode included in the capacitor of the second-stage LC resonator are a same ground conductor;
the same ground electrode, the end-portion electrode of the second-stage LC resonator, and the end-portion electrode of the first-stage LC resonator are on different layers of the multilayer board; and
the end-portion electrode of the second-stage LC resonator and an extension electrode include overlapping portions when viewed from a stacking direction of the multilayer board, the extension electrode being provided by extending the end-portion electrode of the first-stage LC resonator in a planar direction along a same layer as the end-portion electrode of the second-stage LC resonator.

6. The diplexer according to claim 1, wherein
a matching inductor is between the common input/output terminal and the high-band band pass filter; and
a capacitance of the capacitor of the first-stage LC resonator of the high-band band pass filter is larger than a capacitance of the capacitor of the final-stage LC resonator of the high-band band pass filter.

7. The diplexer according to claim 6, further comprising:
a multilayer board including a plurality of base layers stacked on top of one another; wherein
the inductor of the LC resonator of the high-band band pass filter includes a via conductor in the multilayer board, and the capacitor is defined by a capacitance between an end-portion electrode and a ground electrode, which are between different layers of the multilayer board; and
when looking in the stacking direction of the multilayer board, an overlapping area of the end-portion electrode of the first-stage LC resonator of the high-band band pass filter and the ground electrode is larger than an overlapping area of the end-portion electrode of the final-stage LC resonator of the high-band band pass filter and the ground electrode.

8. A diplexer comprising:
a multilayer board including a plurality of base layers stacked on top of one another; wherein
a plurality of via conductors, a plurality of capacitor electrodes, a first ground electrode, and a second ground electrode are in an inside of the multilayer board;
a common input/output terminal, a low-band input/output terminal, a high-band input/output terminal, and a ground terminal are on a surface of the multilayer board;
the ground terminal is connected to the first ground electrode and the second ground electrode;
a plurality of sets of capacitors and inductors are between the common input/output terminal and the low-band input/output terminal, each of the plurality of sets of capacitors and inductors including a capacitor including the first ground electrode and the capacitor electrode that face one another and an inductor including a conductor including the via conductor connected between this capacitor electrode and the second ground electrode;
the common input/output terminal is connected to a first set of the capacitor and the inductor via a matching capacitor, the matching capacitor including at least a pair of the capacitor electrodes facing one another;
the low-band input/output terminal is connected to a second set of the capacitor and the inductor; and
a capacitance of the capacitor of the first set of the capacitor and the inductor is smaller than a capacitance of the capacitor of the second set of the capacitor and the inductor.

9. The diplexer according to claim 8, wherein
a planar line electrode is in an inside of the multilayer board; and
the inductor includes a conductor including the via conductor and the planar line electrode.

10. The diplexer according to claim 1, wherein the capacitor and the inductor of each of the first-stage LC resonator to the final-stage LC resonator of the low-band band pass filter are connected in parallel.

11. The diplexer according to claim 1, wherein the plurality of LC resonators of the low-band band pass filter include the first-stage LC resonator, a second-stage LC resonator, and a third-stage LC resonator defining the final-stage LC resonator.

12. The diplexer according to claim 11, wherein the first-stage LC resonator and the second-stage LC resonator are primarily capacitively coupled by a first coupling capacitor.

13. The diplexer according to claim 12, wherein the second-stage LC resonator and the third-stage LC resonator are primarily capacitively coupled by a second coupling capacitor.

14. The diplexer according to claim 13, wherein the matching capacitor, the first coupling capacitor, and the second coupling capacitor are connected in series between the common input/output terminal and the low-band input/output terminal.

15. The diplexer according to claim 14, wherein the first-stage LC resonator is between a ground and a connecting point of the matching capacitor and the first coupling capacitor.

16. The diplexer according to claim 14, wherein the second-stage LC resonator is between a ground and a connecting point of the first coupling capacitor and the second coupling capacitor.

17. The diplexer according to claim 14, wherein the third-stage LC resonator is between a ground and a connecting point of the second coupling capacitor and the low-band input/output terminal.

18. The diplexer according to claim 1, wherein the capacitor and the inductor of each of the first-stage LC resonator to the final-stage LC resonator of the high-band band pass filter are connected in parallel.

19. The diplexer according to claim 1, wherein the plurality of LC resonators of the high-band band pass filter include the first-stage LC resonator, a second-stage LC resonator, a third-stage LC resonator, and a fourth-stage LC resonator defining the final-stage LC resonator.

20. The diplexer according to claim 19, wherein
the first-stage LC resonator and the second-stage LC resonator are primarily capacitively coupled by a third coupling capacitor;
the second-stage LC resonator and the third-stage LC resonator are primarily capacitively coupled by a fourth coupling capacitor; and
the third-stage LC resonator and the fourth-stage LC resonator are primarily capacitively coupled by a fifth coupling capacitor.
